(19) United States
(12) Patent Application Publication
(10) Pub. No.: US 2020/0100393 A1
(43) Pub. Date: Mar. 26, 2020

(54) MOTOR, PRINTED CIRCUIT BOARD, AND ENGINE COOLING FAN MODULE INCLUDING THE MOTOR

(71) Applicant: Johnson Electric International AG, Murten (CH)

(72) Inventors: Youqing XIANG, Shenzhen (CN); Xiaojun YAN, Shenzhen (CN); Nan ZHENG, Shenzhen (CN); Minghua XIONG, Shenzhen (CN); Yun CHEN, Shenzhen (CN); Bailin BO, Shenzhen (CN); Zhanqi ZHANG, Shenzhen (CN)

(21) Appl. No.: 16/577,500

(22) Filed: Sep. 20, 2019

(30) Foreign Application Priority Data
Sep. 20, 2018 (CN) 201821545108.9
Sep. 20, 2018 (CN) 201821547468.2

(51) Int. Cl. H05K 7/20; H05K 1/18; H02K 11/33

(52) U.S. Cl. CPC H05K 7/20509; H02K 11/33; H05K 1/18

(57) ABSTRACT

A printed circuit board includes a substrate and at least one heat generating electronic component mounted on the substrate. At least one ceramic heat conducting member is embedded into the printed circuit board at positions corresponding to the at least one heat generating electronic component. Side surfaces of the ceramic heat conducting member in contact with the printed circuit board are rough surfaces. Heat dissipation effect of the motor is improved.

### CROSS REFERENCE TO RELATED APPLICATIONS

This non-provisional patent application claims priority under 35 U.S.C. § 119(a) from Patent Application No. 201821547468.2 filed in the People's Republic of China on Sep. 20, 2018, and Patent Application No. 201821545108.9 filed in the People's Republic of China on Sep. 20, 2018.

### FIELD OF THE INVENTION

The present disclosure relates to electric motors, and in particular to a motor, a printed circuit board and a cooling fan module of a vehicle engine including the motor.

### BACKGROUND OF THE INVENTION

Motors, such as those used in engine cooling fan modules of vehicles, are often exposed to high temperatures. Therefore, the power control printed circuit board and/or the signal control printed circuit board of the motor often adopt fire retardant material, and the fire retardant material has the advantages of non-flammable and has the disadvantages of poor thermal conductivity.

### SUMMARY OF THE INVENTION

Hence there is a desire for a new motor having improved heat dissipation effect.

Accordingly, in one aspect thereof, the present disclosure provides a printed circuit board, including a substrate and at least one heat generating electronic component mounted on the substrate. At least one ceramic heat conducting member is embedded inside the printed circuit board at positions corresponding to the at least one heat generating electronic component.

Preferably, the ceramic heat conducting member is an aluminum nitride ceramic block, and side surfaces of the aluminum nitride ceramic block in contact with the printed circuit board are rough surfaces.

Preferably, the ceramic heat conducting member penetrates a top surface and a bottom surface of the substrate.

Preferably, side surfaces of the ceramic heat conducting member in contact with the printed circuit board are provided with a plurality of protrusions.

Preferably, a plurality of notch is defined in side surfaces of the ceramic heat conductive member in contact with the printed circuit board, and the plurality of notch is filled with adhesive to bonding the ceramic heat conductive member and the printed circuit board.

Preferably, an area of a cross section of the ceramic heat conductive member gradually increases in a direction from the top to the bottom surface of the printed circuit board.

Preferably, a cross-sectional shape of the ceramic heat-conducting member perpendicular to an extending direction of the printed circuit board is a trapezoidal shape or an inverted T-shape, and an end face of the ceramic heat conducting member facing the heat-generating electron is smaller than an end face away from the heat generating electronic component.

Preferably, an end face of the ceramic heat conducting member facing the heat-generating electronic component is smaller than an end face away from the heat generating electronic component.

In another aspect thereof, the present disclosure provides a motor comprising a stator, the stator includes a control module and a heat sink, the control module includes the printed circuit board described above, and the heat sink being tightly connected to the printed circuit board.

Preferably, a DC-DC converter, a control unit, and an inverter are mounted on the printed circuit board, the DC-DC converter is configured to convert an external DC voltage into a stepped down voltage which is provide to the control unit, the inverter receives a control signal from the control unit and provides the external DC voltage as the supply voltage of the motor.

Preferably, a first conductive layer is disposed on the ceramic heat conducting member and faces an end surface of the heat generating electronic component, the first conductive layer is electrically connected to the heat generating electronic component, another end face of the ceramic heat conducting member connects the heat sink.

In another aspect thereof, the present disclosure provides an engine cooling fan module including the motor described above, the engine cooling fan module includes a frame and an impeller, and the motor is mounted to the frame for driving the impeller.

Preferably, a DC-DC converter, a control unit, and an inverter are mounted on the printed circuit board, the DC-DC converter is configured to convert an external DC voltage into a stepped down voltage which is provide to the control unit, the inverter receives a control signal from the control unit and provides the external DC voltage as the supply voltage of the motor.

The ceramic heat conducting members are disposed under the heating electronic components on the printed circuit board, which improves the heat dissipation effect of the printed circuit board, thereby improving the heat dissipation effect of the motor. Moreover, the motor is directly driven by the system voltage, instead of being driven by the voltage converted by the DC-DC converter. For a given power, the current in the circuit can be reduced, the power density of the motor can be improved, and the cost can be reduced.

### BRIEF DESCRIPTION OF THE DRAWINGS

A preferred embodiment of the invention will now be described, by way of example only, with reference to figures of the accompanying drawings. In the figures, identical structures, elements or parts that appear in more than one figure are generally labeled with a same reference numeral in all the figures in which they appear. Dimensions of components and features shown in the figures are generally chosen for convenience and clarity of presentation and are not necessarily shown to scale. The figures are listed below.

FIG. 1 is a schematic diagram of a motor according to an embodiment of the present disclosure;

FIG. 2 shows the internal structure of the motor of FIG. 1;

FIG. 3 is an exploded schematic view of a stator seat of the motor of FIG. 1;

FIG. 4 is a schematic side view of the stator seat of the motor of FIG. 1;

FIG. 5 is a longitudinal sectional view of the stator seat along the line A-A of FIG. 4;

FIG. 6 is a schematic cross-sectional view of a printed circuit board and a heat sink of the motor of FIG. 1;

FIG. 7 is a schematic cross-sectional view of a printed circuit board and a heat sink of another embodiment of the motor of FIG. 1;

FIG. 8 is a schematic circuit diagram of a motor of an embodiment of the present disclosure;

FIG. 9 is a schematic circuit diagram of a DC-DC converter shown in FIG. 8;

FIG. 10 is a schematic diagram of a cooling fan module of a vehicle's engine according to an embodiment of the present disclosure.

### DETAILED DESCRIPTION OF THE PREFERRED EMBODIMENTS

Embodiments of the present disclosure will be described in greater detail with reference to the drawings. It should be noted that the figures are illustrative rather than limiting. The figures are not drawn to scale, do not illustrate every aspect of the described embodiments, and do not limit the scope of the present disclosure. Unless otherwise specified, all technical and scientific terms used in this disclosure have the ordinary meaning as commonly understood by people skilled in the art.

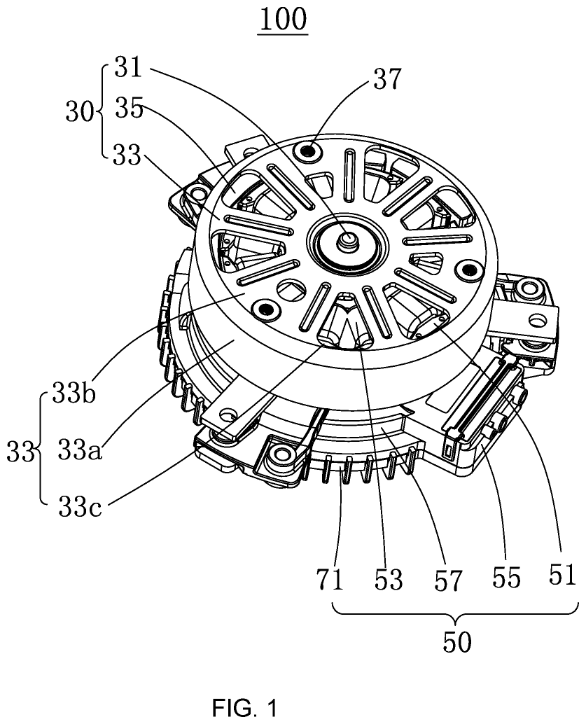

Referring to FIG. 1, a motor 100 in accordance with an embodiment of the present disclosure is a permanent magnet brushless outer rotor motor, which includes a rotor 30 and a stator 50.

The stator 50 includes a stator core 51 made of magnetic material, stator windings 53 wound around the stator core 51, a connector 55 for supplying power to the stator windings 53, a stator seat 57 for supporting the stator core 51, a heat sink 71 mounted to the stator seat 57, and a control module. The heat sink 71 is made of metal heat conductive material such as copper or aluminum. The connector 55 is mounted to the stator seat 57 for connection to an external power source (not shown).

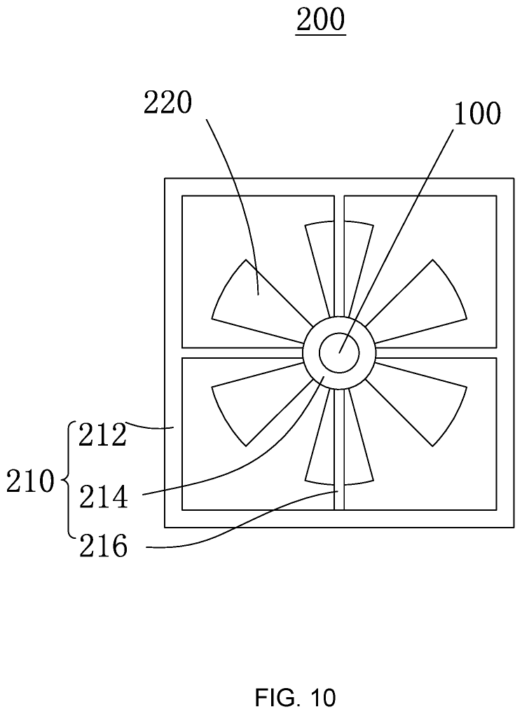

The rotor 30 includes a rotating shaft 31, a rotor housing 33 having a cup shape fixed to the rotating shaft 31, and a plurality of permanent magnets 35 mounted on an inner wall of the rotor housing 33. The rotor housing 33 includes an annular side wall 33a and a bottom portion 33b located at an axial end of the annular side wall 33a. The bottom portion 33b is fixed to the rotating shaft 31 so as to rotate with the rotating shaft 31. The annular side wall 33a surrounds and rotates around the rotating shaft 31. The permanent magnet 35 is attached to an inner circumferential surface of the annular side wall 33a. In this embodiment, a plurality of substantially fan-shaped through holes 33c is defined in the bottom portion 33b and distributed around the rotating shaft 31, so that outside air can enter the interior of the motor 100 to cool the stator core 51 and the stator windings 53 to improve cooling effect of the motor 100. The bottom portion 33b of the rotor housing 33 forms a plurality of mounting positions 37 for fixedly mounting the rotor 30 to an impeller 220 (see FIG. 10) so that the rotor 30 can drive the impeller to rotate.

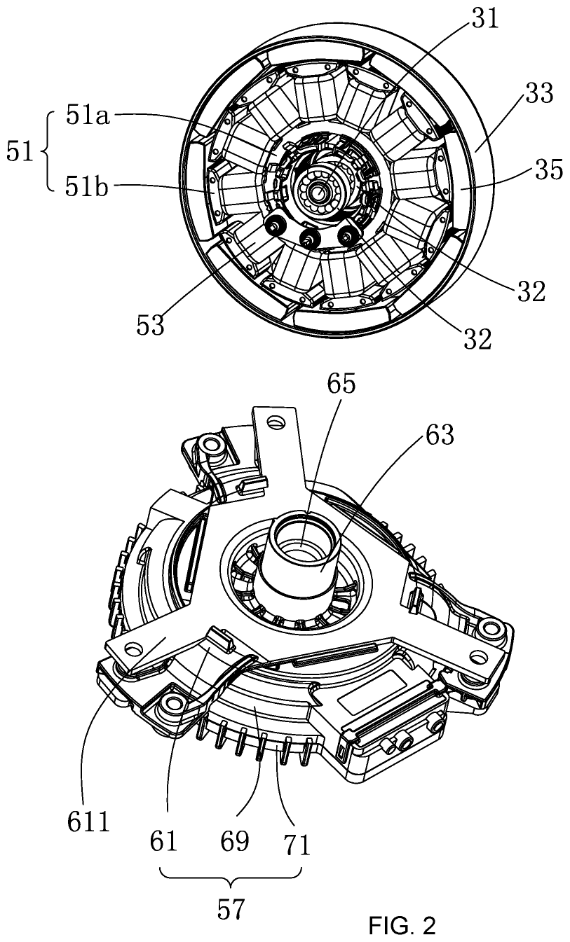

Referring to FIG. 2, the rotating shaft 31 is rotatably mounted to the stator seat 57 through two bearings 32. The stator seat 57 includes a cylindrical supporting column 63. Two bearing positions 65 are formed in the supporting column 63 for mounting corresponding bearings 32. In this manner, the rotor 30 can rotate relative to the stator seat 57.

The stator core 51 includes an annular yoke portion 51a, and a plurality of stator teeth 51b extending outwardly from the annular yoke portion 51a. The stator windings 53 are wound around the stator teeth 51b. The stator core 51 and stator windings 53 are fixedly mounted to the stator seat 57.

The stator seat 57 includes an upper case 69 and a supporting seat 61 mounted to the upper case 69. The upper case 69 and the heat sink 71 are snap-fitted together and defining a receiving space therebetween for receiving the control module therein. The supporting seat 61 includes three mounting feet spaced apart in the circumferential direction for mounting to an external device and the supporting column 63 for supporting the stator core 51. A spacer 611 is disposed between the supporting seat 61 and the stator core 51. The spacer 611 is mounted to the supporting seat 61 for isolating the stator windings 53 from the supporting seat 61. The shape of the spacer 611 is matched with the supporting seat 61.

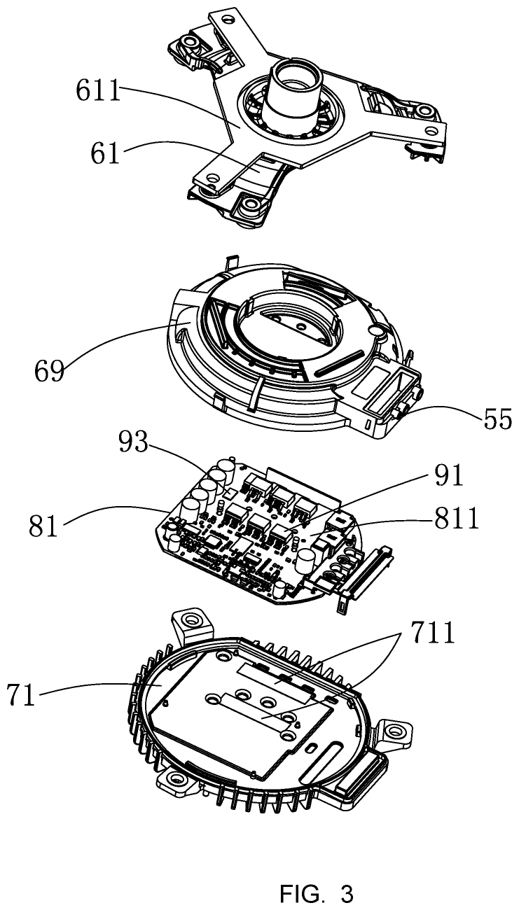

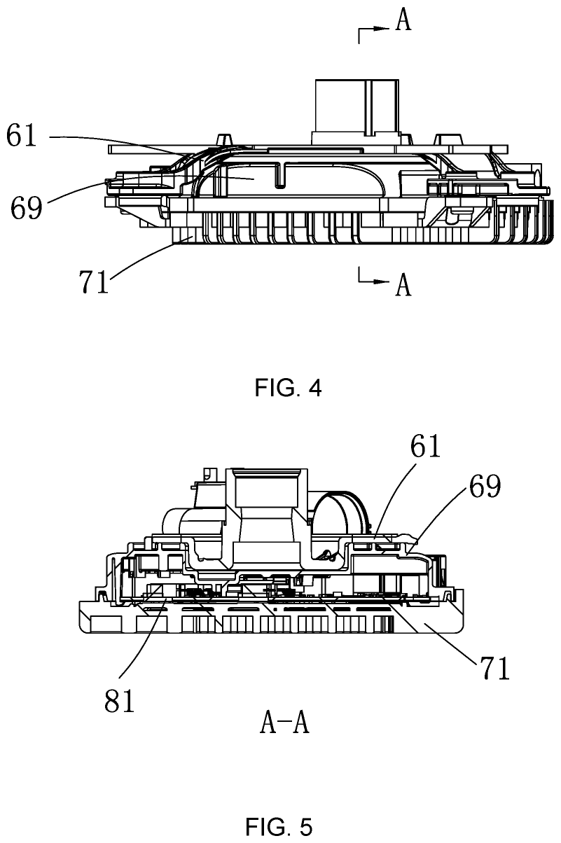

Referring to FIGS. 3-5, in this embodiment, the control module includes a circuit board 81 and a plurality of heat generating electronic components 91 mounted on the printed circuit board 81. The upper case 69 and the heat sink 71 are clasped together and a receiving space is formed there between for receiving the printed circuit board 81 and the plurality of heat generating electronic components 91. The connector 55 is attached to the printed circuit board 81 to be electrically connected with the heat generating electronic components 91. The printed circuit board 81 includes a substrate 811. The substrate 811 includes a top surface and a bottom surface. The heat generating electronic components 91 are mounted on the top surface of the substrate 811. The heat sink 71 is located under the bottom surface of the substrate 811. The substrate 811 is made of fire retardant material, for example, FR4 material.

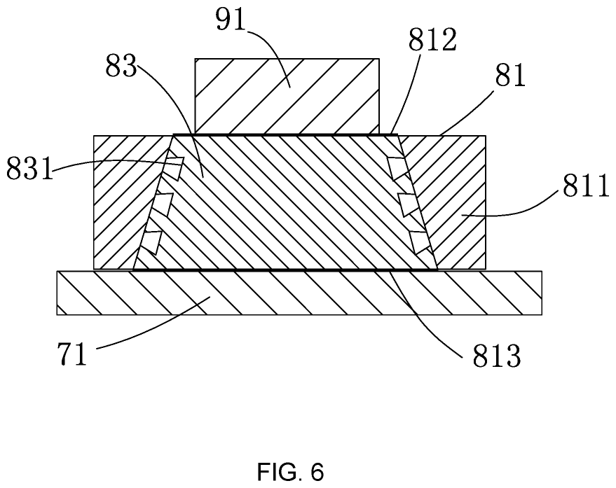

Referring to FIG. 6, the heat generating electronic components 91, such as metal-oxide semiconductor field-effect transistors (MOSFETs), are soldered on the top surface of the substrate 811. It can be understood that when the heat generating electronic components 91 are working, heat is generated therein, and the heat generating electronic components 91 becomes a heat source.

In order to improve the heat dissipation effect of the printed circuit board 81, a plurality of heat conducting members which is made of ceramic material is embedded in the substrate 811 of the printed circuit board 81 for heat exchangers. In the present embodiment, the heat conducting member is an aluminum nitride ceramic block 83. The aluminum nitride ceramic block 83 is thermally conductive, but electrically non-conductive. The aluminum nitride ceramic block 83 extends along the thickness direction of the printed circuit board 81. Preferably, the aluminum nitride ceramic block 83 penetrates the top and bottom surfaces of the printed circuit board 81 for rapidly transferring the heat generated by the heat generating electronic components 91 from the top surface to the bottom surface of the circuit board 81. The heat is further dissipated through the heat sink 71. The embedded heat conducting members can effectively improve the heat dissipation effect of the printed circuit board 81 along its thickness. Preferably, the position of the aluminum nitride ceramic block 83 is facing the position of the heat generating electronic component 91, and a first conductive layer 812 and a second conductive layer 813 are respectively disposed on both end surfaces of the aluminum nitride ceramic block 83. The first conductive layer 812 faces the heat generating electronic component 91, and the second conductive layer 813 faces the heat sink 71. One thermal conductive pad of the heat generating electronic component 91 is electrically connected to the first conductive layer 812. For example, a thermal pad of the MOSFET may be directly soldered to the first conductive layer 812, so that the heat generated by the MOSFET can be quickly transferred to the aluminum nitride ceramic block 83. More preferably, the area of the aluminum nitride ceramic block 83 facing the heat generating electronic component 91 is larger than the area of the heat generating electronic component 91 so as to absorb and transfer as much heat as possible from the heat generating electronic component 91. Preferably, a MOSFET can be provided with an aluminum nitride ceramic block 83. It is understood that, if the thermal conductive pads of multiple MOSFETs are connected together, the multiple MOSFETs can share one aluminum nitride ceramic block 83. The heat sink 71 is soldered to the second conductive layer 813 to fix the printed circuit board 81 and the heat sink 71 together. At least one soldering positions 711 (see FIG. 3) are formed on the heat sink 71 for soldering the heat sink 71 to the second conductive layer 813. Preferably, the materials of the first conductive layer 812 and the second conductive layer 813 are the same, such as copper foil, solder paste, copper paste and the like.

In one embodiment, side surfaces of the aluminum nitride ceramic block 83 in contact with the printed circuit board 81 are rough surface, which increases the friction and improves stability of contact between the aluminum nitride ceramic block 83 and the printed circuit board 81. Preferably, a plurality of protrusions are provided on the side surfaces of the aluminum nitride ceramic block 83 in contact with the printed circuit board 81, and the friction between the aluminum nitride ceramic block 83 and the circuit board 81 can be further increased.

In one embodiment, the aluminum nitride ceramic block 83 is soldered or bonded to the substrate 811 of the printed circuit board 81 to enable the aluminum nitride ceramic block 83 to be firmly connected to the printed circuit board 81.

In one embodiment, the side surfaces of the aluminum nitride ceramic block 83 in contact with the printed circuit board 81 is provided with a plurality of notches 831 which is filled with an adhesive such as glue or the like to realize the adhesive connection between the aluminum nitride ceramic block 83 and the substrates 811 of the printed circuit board 81.

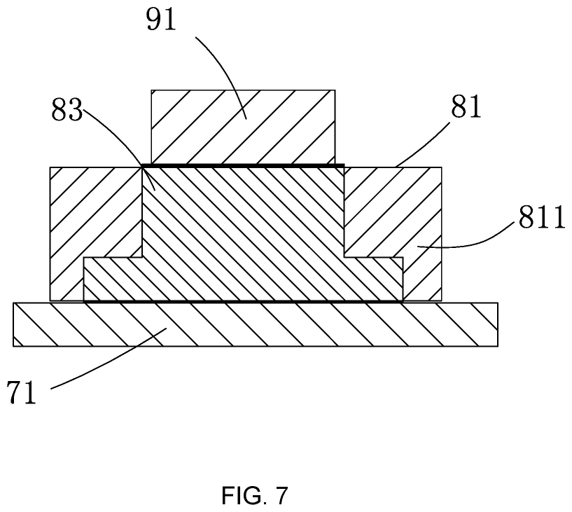

In one embodiment, the area of the cross section of the aluminum nitride ceramic block 83 parallel to the printed circuit board 81 is gradually increased along the direction from the top to the bottom surfaces of the printed circuit board 81. For example, the cross-sectional shape of the aluminum nitride ceramic block 83 perpendicular to the extending direction of the printed circuit board 81 is trapezoidal, and the dimension of the end face of the aluminum nitride ceramic block 83 facing the heat generating electronic component 91 is smaller than that of the end face of the aluminum nitride ceramic block 83 facing the heat generating electronic component 91. The end face of the aluminum nitride ceramic block 83 facing the heat generating electronic component 91 is small, which does not affect the arrangement of the electronic components on the top surface of the printed circuit board 81, and the area of the end surface facing the heat sink 71 is large, such that the heat conduction area between the aluminum nitride ceramic block 83 and the heat sink 71 is increased. In other embodiments, the cross-sectional shape of the aluminum nitride ceramic block 83 perpendicular to the printed circuit board 81 may be other shapes as long as the heat dissipation efficiency can be improved as much as possible, such as an inverted T shape or a stepped shape (see FIG. 7).

Preferably, the motor 100 has only one printed circuit board 81, that is the power control circuit and signal control circuit are integrated in the printed circuit board 81, which can help reduce the complexity, cost, and size of the motor. Correspondingly, the connector 55 at least includes a terminal connected to the external power source and a terminal connected to a signal source.

Alternatively, the printed circuit board 81 may include two connectors, one of which is a power connector, the other is a signal connector.

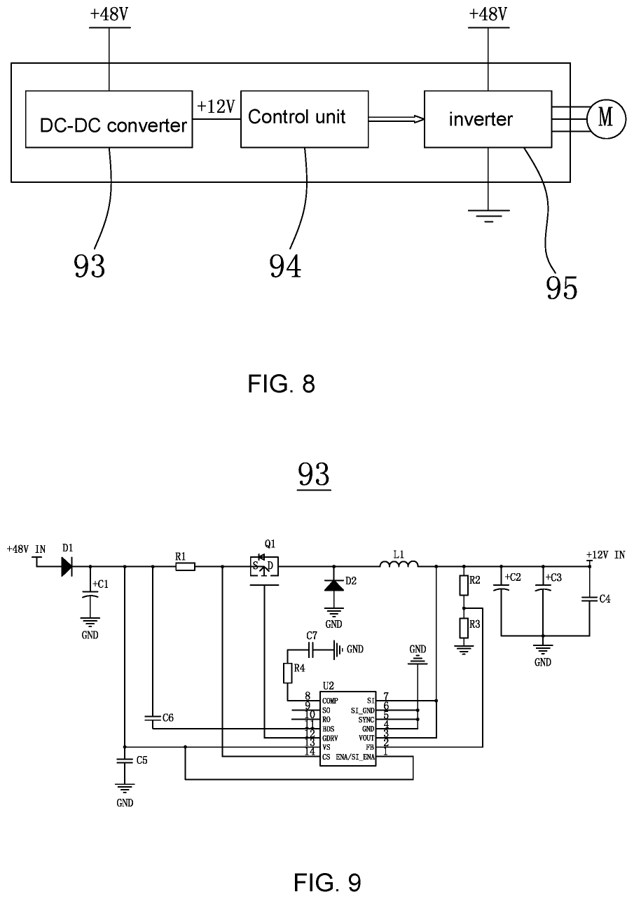

Referring to FIG. 8, a circuit schematic diagram of the motor 100 is provided. A DC-DC converter 93, a control unit 94, and an inverter 95 are disposed on the circuit board 81 of the motor 100.

In this embodiment, the DC-DC converter 93 is configured to step down the voltage from a higher external DC voltage (for example a 48V voltage from the battery of the vehicle) to a lower voltage needed at the load such as the 12V control unit 94. The control unit 94 is coupled to the inverter 95 for outputting a PWM (pulse width modulation) signal to the inverter 95 to control the motor 100, for example to control the motor speed. The inverter 95 is connected to the battery of the vehicle and receives the external DC voltage (such as a 48V voltage) supplied from the battery as the power supply voltage of the motor 100.

Referring to FIG. 9, the DC-DC converter 93 is a 48-12 volt voltage converter, and includes a control chip U2, an inductor L1, diodes D1-D2, capacitors C1-C7, and resistors R1-R4. An anode of the diode D1 receives the 48V voltage provided by the battery, a cathode of the diode D1 is connected to a source of the MOSFET Q1 through the resistor R1, and a VS pin of the control chip U2. A gate of the MOSFET Q1 is connected to a GDRV pin of the control chip U2. A drain of the MOSFET Q1 is connected to an output terminal of the DC-DC converter 93 through the inductor L1. The MOSFET Q1 functions as a power switch, and is turned on or off according to the control signal of the control chip U2. The stepped down voltage, for example 12V, is output from the output terminal to the control unit 94, the inductor L1 is used to store energy. The output terminal is also grounded through the resistors R2 and R3, a node between the resistors R2 and R3 is connected to a FB pin of the control chip U2, and output current at the output terminal is output to the control chip U2. When the output current is higher than a preset value, the control chip U2 performs over current protection, such as stop outputting the output signal to the MOSFET Q1. The output terminal can also be grounded through capacitors C2-C4 connected in parallel to stabilize the current. The drain of the MOSFET Q1 is connected to a cathode of the diode D2, and an anode of the diode D2 is grounded. The cathode of diode D1 is grounded through capacitors C1 and C5 connected in parallel, and is also connected to a BDS pin of control chip U2 through capacitor C6. The COMP pin of control chip U2 is grounded through resistor R4 and capacitor C7. A CS pin of the control chip U2 is connected to the source of the MOSFET Q1. On the circuit board 81, the aluminum nitride ceramic block 83 corresponds to the position of the MOSFET Q1. Thus, the heat generated by the MOSFET Q1 can be quickly conducted to the aluminum nitride ceramic block 83 and dissipated through the heat sink 71. The aluminum nitride ceramic block 83 may be disposed at corresponding mounting positions of the plurality of MOSFETs of the inverter 95 to effectively dissipate heat from the heat generating electronic components 91.

Referring to FIG. 10, a cooling fan module 200 of a vehicle engine according to another embodiment of the present disclosure is shown. The cooling fan module 200 includes a frame 210, an impeller 220, and the motor 100. The frame 210 includes a rectangular or circular outer frame 212, an inner frame 214 disposed at the center of the outer frame 212, and a plurality of supporting portions 216 connected between the outer frame 212 and the inner frame 214. The motor 100 is mounted to the inner frame 214 and configured to drive the impeller 220. Due to the cooling fan module 200 including the motor 100, the cooling fan module 200 has good heat dissipation performance, good cooling effect, and long cycle life.

Those skilled in the art can understand that the input voltage received by the DC-DC converter 93 is not limited to 48V, and may be any value between 24-72V, such as 24V, 48V, 60V, 72V and the like. The voltage output by the DC-DC converter 93 is not limited to 12V, and may be any value between 8-25V.

In one embodiment of the present disclosure, the power of the battery of the vehicle (such as 48V) is directly provided to the motor, because the voltage of the vehicle is higher than the voltage output by the DC-DC converter, for a given power of the cooling fan module 200, the current flowing through the motor 100 is greatly reduced. Other components on the circuit board 81 can also be selected with components with a small rated current, thereby reducing the overall cost.

In the description and claims of the present application, each of the verbs “comprise”, “include”, “contain” and “have”, and variations thereof, are used in an inclusive sense, to specify the presence of the stated item or feature but do not preclude the presence of additional items or features.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable sub-combination.

Although the invention is described with reference to one or more embodiments, the above description of the embodiments is used only to enable people skilled in the art to practice or use the invention. It should be appreciated by those skilled in the art that various modifications are possible without departing from the spirit or scope of the present invention. The embodiments illustrated herein should not be interpreted as limits to the present invention, and the scope of the invention is to be determined by the appended claims.

1. A printed circuit board, comprising a substrate and at least one heat generating electronic component mounted on the substrate, wherein at least one ceramic heat conducting member is embedded inside the printed circuit board at positions corresponding to the at least one heat generating electronic component.

2. The printed circuit board according to claim 1, wherein the ceramic heat conducting member is an aluminum nitride ceramic block, and side surfaces of the aluminum nitride ceramic block in contact with the printed circuit board are rough surfaces.

3. The printed circuit board according to claim 1, wherein the ceramic heat conducting member penetrates a top surface and a bottom surface of the substrate, and is soldered or bonded to the substrate.

4. The printed circuit board according to claim 1, wherein side surfaces of the ceramic heat conducting member in contact with the printed circuit board are provided with a plurality of protrusions.

5. The printed circuit board according to claim 1, wherein a plurality of notch is defined in side surfaces of the ceramic heat conductive member in contact with the printed circuit board, and the plurality of notch is filled with adhesive to bonding the ceramic heat conductive member and the printed circuit board.

6. The printed circuit board according to claim 1, wherein an area of a cross section of the ceramic heat conductive member gradually increases in a direction from a top to a bottom surface of the printed circuit board.

7. The printed circuit board according to claim 1, wherein a cross-sectional shape of the ceramic heat conducting member perpendicular to an extending direction of the printed circuit board is a trapezoidal shape or an inverted T-shape, and an end face of the ceramic heat conducting member facing the heat generating electronic component is smaller than an end face away from the heat generating electronic component.

8. The printed circuit board according to claim 1, wherein an end face of the ceramic heat conducting member facing the heat generating electronic component is smaller than an end face away from the heat generating electronic component.

9. A motor comprising a stator, the stator comprising a control module and a heat sink, wherein the control module comprises the printed circuit board according to claim 1, and the heat sink being tightly connected to the printed circuit board.

10. The motor according to claim 9, wherein a DC-DC converter, a control unit, and an inverter are mounted on the printed circuit board, the DC-DC converter is configured to convert an external DC voltage into a stepped down voltage which is provide to the control unit, the inverter receives a control signal from the control unit and provides the external DC voltage as the supply voltage of the motor.

11. The motor according to claim 9, wherein a first conductive layer is disposed on the ceramic heat conducting member and faces an end surface of the heat generating electronic component, the first conductive layer is electrically connected to the heat generating electronic component, another end face of the ceramic heat conducting member connects the heat sink.

12. An engine cooling fan module comprising the motor according to claim 9, wherein the engine cooling fan module comprises a frame and an impeller, the motor is mounted to the frame for driving the impeller.

13. The engine cooling fan module according to claim 12, wherein a DC-DC converter, a control unit, and an inverter are mounted on the printed circuit board, the DC-DC converter is configured to convert an external DC voltage into a stepped down voltage which is provide to the control unit, the inverter receives a control signal from the control unit and provides the external DC voltage as the supply voltage of the motor.

14. The engine cooling fan module according to claim 12, wherein a first conductive layer is disposed on the ceramic heat conducting member and faces an end surface of the heat generating electronic component, the first conductive layer is electrically connected to the heat generating electronic component, another end face of the ceramic heat conducting member connects the heat sink.
